(19) United States
(12) Patent Application Publication
(10) Pub. No.: US 2010/0288439 A1
(43) Pub. Date: Nov. 18, 2010

(54) TOP PLATE AND PLASMA PROCESS APPARATUS EMPLOYING THE SAME

(75) Inventors: Kiyotaka Ishibashi, Hyogo (JP); Tadahiro Ohmi, Miyagi (JP); Tetsuya Goto, Miyagi (JP); Masahiro Okesaku, Ishikawa (JP)

Correspondence Address: IPUSA, P.L.L.C, 1054 31ST STREET, N.W., Suite 400, Washington, DC, 20007, US

(73) Assignees: TOKYO ELECTRON LIMITED, MINATO-KU (JP); NATIONAL UNIVERSITY CORPORATION TOHOKU UNIVERSITY, AOBA-KU, MIYAGI (JP)

(21) Appl. No.: 12/675,273

(22) PCT Filed: Aug. 21, 2008
(86) PCT No.: PCT/JP2008/064915

§ 371 Date: Jul. 21, 2010

(30) Foreign Application Priority Data
Sep. 6, 2007 (JP) 2007-232099

(51) Int. Cl. H01L 21/465; C23C 16/50; C23C 16/511; C23C 16/455; H01L 21/46; B26F 1/00

(52) U.S. Cl. 156/345.33; 118/723 R; 83/30; 257/E21.482; 257/E21.485

(57) ABSTRACT

A disclosed top plate that is configured as a solid part and provided in an opening in a ceiling portion of a plasma process chamber whose inside is evacuatable to vacuum includes plural gas conduits formed in a horizontal direction of the top plate; and gas ejection holes that are open in a first surface of the top plate, the first surface facing the inside of the plasma process chamber and in gaseous communication with the plural gas conduits.

### TECHNICAL FIELD

The present invention relates to a plasma process apparatus used when a semiconductor wafer and the like are processed by applying plasma generated by microwaves onto the semiconductor wafer and the like, and a top plate for use in the plasma process apparatus.

### BACKGROUND ART

Along with recent miniaturization and high integration of semiconductor products, a plasma process apparatus is frequently employed for film deposition, etching, aching, and the like in semiconductor product fabrication processes. Especially, a plasma process apparatus where plasma is generated using microwaves or high frequency waves tends to be more frequently used, because high density plasma can be stably generated even in a high vacuum environment at a relatively low pressure of 0.1 through 10 Pa.

Such a plasma process apparatus is disclosed in Patent Documents 1 through 7. A generic plasma process apparatus is schematically explained with reference to FIG. 1. FIG. 1 is a schematic view illustrating a related art plasma process apparatus employing microwaves.

In FIG. 1, a plasma process apparatus 2 is provided with a susceptor 6 on which a semiconductor wafer W is placed in a process chamber 4 that can be exhausted to vacuum. In a ceiling portion opposing the susceptor 6, a disk-shaped top plate 8 is hermetically provided that is made of aluminum nitride, quartz, and the like and allows microwaves to pass through. In addition, a gas nozzle 10 for introducing a predetermined gas into the process chamber 4 as a gas introduction portion is provided in a sidewall of the process chamber 4.

On the upper surface of the top plate 8, there are a disk-shaped planar antenna member 12 having a thickness of several millimeters, and a slow wave structure 14 made of, for example, a dielectric material in order to shorten the wavelength of the microwaves in a radius direction of the planar antenna member 12. The planar antenna member 12 has plural slots 16, which are through holes having, for example, an oblong opening shape. Generally, the slots 16 are arranged in a concentric or spiral pattern.

An inner conductive body 18A of a co-axial waveguide pipe 18 is connected to a central portion of the planar antenna member 12. An oscillation mode of microwaves having a frequency of, for example, 2.45 GHz generated by a microwave generator 20 is converted into a predetermined mode by a mode converter 22, and the microwaves are guided to the central part of the planar antenna member 12. Then, the microwaves propagate in a radius direction in the planar antenna member 12, and are downwardly radiated from the slots 16 of the planar antenna member 12 into the process chamber 4 through the top plate 8. The microwaves generate plasma in a process space S in the process chamber 4, so that the semiconductor wafer can undergo a predetermined plasma process such as film deposition and etching.

Regarding such a plasma process, technology has been proposed (see Patent Document 4, or the like) where a showerhead is used in the place of the gas nozzle 10 as the gas introduction portion, and further the top plate 8 can serve as the showerhead because it is important to uniformly supply the gas into the process space S. In this case, the top plate 8 cannot be made of metal because the microwaves cannot penetrate through such a top plate. Therefore, the top plate 8 needs to be made of quartz or ceramic materials, which are more difficult to be machined than metal. For example, such a top plate 8 is made by preparing a showerhead body and a cover plate, forming gas distribution grooves and gas ejection holes in the showerhead body, and hermetically coupling the showerhead body and the cover plate with a sealing member such as an O-ring interposed therebetween.

Patent Document 1: Japanese Patent Application Laid-Open Publication No. H3-191073

Patent Document 2: Japanese Patent Application Laid-Open Publication No. H5-343334

Patent Document 3: Japanese Patent Application Laid-Open Publication No. H9-63793

Patent Document 4: Japanese Patent Application Laid-Open Publication No. 2002-299240

Patent Document 5: Japanese Patent Application Laid-Open Publication No. H9-181052

Patent Document 6: Japanese Patent Application Laid-Open Publication No. 2003-332326

Patent Document 7: Japanese Patent Application Laid-Open Publication No. 2004-39972

### SUMMARY OF INVENTION

Problems to be Solved by the Invention

Because such a top plate serving as the showerhead is not highly resistant to an increased temperature because an O-ring is used as the sealing member, there is a limit to an amount of electricity supplied to generate plasma.

In addition, when abnormal electrical discharge may take place in a portion where a stronger electric field is applied, such abnormal electric discharge may damage the O-ring, and the probability of gas leak may be increased. In addition, a gap may be caused between the showerhead body and the cover plate, so that thermal communication from the showerhead body to the cover plate is degraded, which may damage the showerhead because of thermal stress.

Moreover, when the top plate is configured of the two members as stated above, each member is likely to be damaged. Therefore, highly pressurized gas cannot be used in order to supply a larger amount of gas, and thus there is a limit to an amount of gas to be supplied. In this case, it may be thought to increase a thickness of the top plate. However, when the top plate is made thick, thermal conductivity of the top plate is degraded, and the microwaves or the like penetrating the top plate may be adversely influenced, so that electric field may be unevenly distributed.

The present invention has been made in order to effectively solve the above problems. The present invention is directed to a top plate serving as a showerhead and a plasma process apparatus employing the same where a large amount of gas may be supplied by forming such a top plate as a solid part to enhance strength and resistance of the top plate to an increase in temperature.

### Means of Solving the Problems

A first aspect of the present invention provides a top plate that is configured as a solid part and provided in an opening in a ceiling portion of a plasma process chamber whose inside is evacuatable to vacuum. The top plate includes plural gas conduits formed in a horizontal direction of the top plate; and gas ejection holes that are open in a first surface of the top plate, the first surface facing the inside of the plasma process chamber and being in gaseous communication with the plural gas conduits.

A second aspect of the present invention provides a top plate according to the first aspect, wherein the plural gas conduits are open at respective ends as a gas inlet in a side surface of the top plate and extend toward a center portion of the top plate.

A third aspect of the present invention provides a top plate according to the second aspect, wherein the plural gas conduits include first gas conduits formed in a radial pattern toward the center portion of the top plate; and second gas conduits formed in parallel with the first gas conduits.

A fourth aspect of the present invention provides a top plate according to the first aspect, wherein one of the plural gas conduits is in gas communication with at least another one of the plural gas conduits, and includes a gas inlet open in one of the first surface and a second surface of the top plate, the second surface opposing the first surface.

A fifth aspect of the present invention provides a top plate according to the fourth aspect, wherein the plural gas conduits are formed in a radial pattern in the top plate, and wherein one of the plural gas conduits is in gaseous communication, at an end portion existing in a center portion of the top plate, with at least another one of the gas conduits.

A sixth aspect of the present invention provides a top plate according to the fourth aspect, wherein the plural gas conduits include a first group of the gas conduits that extend toward a center portion of the top plate; and a second group of the gas conduits that are in gaseous communication with the first group of the gas conduits.

A seventh aspect of the present invention provides a top plate according to the fourth aspect, wherein the gas ejection holes in gaseous communication with the plural gas conduits are grouped into first zone gas ejection holes positioned in an inner circumferential portion of the top plate and second zone gas ejection holes positioned in an outer circumferential portion of the top plate, wherein the plural gas conduits in gaseous communication with the first zone gas ejection holes are arranged in a radial pattern and in gaseous communication with one another at end portions existing in a center portion of the top plate, and wherein the plural gas conduits in gaseous communication with the second zone gas ejection holes include a first group of the gas conduits that extend toward the center portion of the top plate and a second group of gas conduits that are in gaseous communication with the first group of the gas conduits

An eighth aspect of the present invention provides a top plate according to the fourth aspect, wherein the gas ejection holes in gaseous communication with the plural gas conduits are grouped into first zone gas ejection holes positioned in an inner circumferential portion of the top plate and second zone gas ejection holes positioned in an outer circumferential portion of the top plate, wherein the plural gas conduits in gaseous communication with the first zone gas ejection holes include a first group of the gas conduits that extend toward the center portion of the top plate and a second group of the gas conduits that are in gas communication with the plural gas conduits of the first group, and wherein the plural gas conduits in gaseous communication with the second zone gas ejection holes include the second group of the gas conduits that are in gas communication with the plural gas conduits of the first group.

A ninth aspect of the present invention provides a top plate according to the first aspect, wherein the gas ejection holes in gaseous communication with the plural gas conduits are grouped into first zone gas ejection holes positioned in an inner circumferential portion of the top plate and second zone gas ejection holes positioned in an outer circumferential portion of the top plate; wherein part of the plural gas conduits are in gaseous communication with one of the first zone gas ejection holes and the second zone gas ejection holes, have openings at respective ends in a side surface of the top plate, and extend toward the center portion of the top plate; and wherein the remaining gas conduits include a first group of gas conduits that are in gaseous communication with the other one of the first zone gas ejection holes and the second zone gas ejection holes, and extend toward the center portion of the top plate, and a second group of gas conduits that are in gaseous communication with the plural gas conduits of the first group.

A tenth aspect of the present invention provides a top plate according to the first aspect, wherein the plural gas conduits include ring-shaped gas conduits arranged in a concentric pattern, and gas conduits that intersect to be in gaseous communication with the ring-shaped gas conduits.

An eleventh aspect of the present invention provides a top plate according to the first aspect, wherein the plural gas conduits are formed in a grid pattern.

A twelfth aspect of the present invention provides a top plate according to any one of the first through the eleventh aspects, wherein porous dielectric bodies having an aeration property are mounted into the corresponding gas ejection holes.

A thirteenth aspect of the present invention provides a top plate according to any one of the first through the eleventh aspects, wherein ceramic materials having fine holes are mounted into the corresponding gas ejection holes.

A fourteenth aspect of the present invention provides a top plate according to the first through the thirteenth aspects, wherein a coolant conduit through which a coolant flows is formed in the top plate.

A fifteenth aspect of the present invention provides a plasma process apparatus including a process chamber that has an opening in a ceiling portion thereof and whose inside is evacuatable to vacuum; a susceptor that is provided in the process chamber and on which an object to be processed is placed; a top plate according to any one of the first through the fourteenth aspects and provided to the opening of the process chamber; an electromagnetic wave introduction portion that introduces electromagnetic waves into the process chamber through the top plate; and a gas introduction portion that supplies a gas to the gas conduits formed in the top plate.

A sixteenth aspect of the present invention provides a plasma process apparatus according to the fifteenth aspect, wherein the gas supplying portion includes a ring-shaped gas introduction port that is provided in a circumference of the top plate and supplies a gas to the gas conduits.

A seventeenth aspect of the present invention provides a plasma process apparatus according to the fifteenth aspect, wherein the gas supplying portion includes a gas supplying conduit that vertically extends in a sidewall of the process chamber and is in gaseous communication with a gas inlet of the gas conduits.

An eighteenth aspect of the present invention provides a plasma process apparatus according to any one of the fifteenth through the seventeenth aspects, wherein the process chamber is provided with a gas introduction portion.

A nineteenth aspect of the present invention provides a method of manufacturing a top plate to be provided in an opening of a ceiling portion of a plasma process chamber whose inside is evacuatable to vacuum, the method including steps of forming plural gas conduits inside the top plate by perforating the top plate from a side surface of the top plate; and forming plural gas ejection holes to be in gaseous communication with the gas conduits by perforating the top plate from a surface of the top plate.

A twentieth aspect of the present invention provides a method according to the nineteenth aspect, further including a step of mounting porous dielectric bodies having an aeration property into the corresponding gas ejection holes.

A twenty-first aspect of the present invention provides a method of manufacturing a top plate to be provided in an opening of a ceiling portion of a plasma process chamber whose inside is evacuatable to vacuum, the method including steps of: forming plural gas conduits inside a half-finished product by perforating the half-finished product from a side surface of the half-finished product; forming plural gas ejection holes to be in gaseous communication with the gas conduits by perforating the half-finished product from a surface of the half-finished product; and sintering the half-finished product.

A twenty-second aspect of the present invention provides a method according to the twenty-first aspect, further including steps of: forming a gas inlet open in one of an upper surface and a lower surface of the half-finished product so that the gas inlet is in gaseous communication with at least one of the plural gas conduits in the half-finished product; and closing openings of the gas conduits formed in the side surface of the half-finished product.

A twenty-third aspect of the present invention provides a method according to the twenty-first or the twenty-second aspect, further including a step of mounting porous dielectric bodies having an aeration property to the corresponding gas ejection holes.

A twenty-fourth aspect of the present invention provides a method according to any one of the twenty-first through the twenty-third aspects, further including a step of forming a coolant conduit through which a coolant flows by perforating the half-finished product from the side surface of the half-finished product.

### EFFECTS OF THE INVENTION

According to a top plate and a plasma process apparatus employing the same according to an embodiment of the present invention, the following excellent effects can be demonstrated.

Because a top plate according to an embodiment of the present invention is configured as a solid part to include plural gas conduits formed in a horizontal direction of the top plate, and gas ejection holes that are in gaseous communication with the gas conduits and open in a surface of the top plate, the surface facing an inside of the process chamber, strength of the top plate can be improved, and resistance to an increased temperature can be enhanced, thereby supplying a larger amount of gas by increasing a supplying pressure of the gas.

### BRIEF DESCRIPTION OF THE DRAWINGS

FIG. 1 is a schematic view illustrating a related art plasma process apparatus employing microwaves.

FIG. 2 is a schematic diagram illustrating a plasma process apparatus employing a top plate according to a first example of the present invention.

FIG. 3A is an enlarged cross-sectional view illustrating the top plate and portions around the top plate in the plasma process apparatus.

FIG. 3B illustrates a modified example of the top plate according to the first example.

FIG. 4 is a cross-sectional view taken along a horizontal plane, illustrating gas conduits in the top plate.

FIG. 5 is a side view of the top plate.

FIG. 6A is a cross-sectional view illustrating a partial configuration of gas ejection holes.

FIG. 6B is another cross-sectional view illustrating a partial configuration of gas ejection holes.

FIG. 6C is a cross-sectional view illustrating members mounted into the gas ejection holes.

FIG. 6D is a plan view of one of the members illustrated in FIG. 6C.

FIG. 7 is a cross-sectional view taken along a horizontal plane of the top plate, illustrating a part of gas conduits of the top plate according to a modified example of Example 1.

FIG. 8 is a partial enlarged cross-sectional view illustrating a vicinity of the top plate according to Example 2.

FIG. 9 is a cross-sectional view taken along a horizontal plane, illustrating a part of the top plate according to Example 2.

FIG. 10 is a side view of the top plate according to Example 2.

FIG. 11 is a partial enlarged cross-sectional view illustrating a vicinity of the top plate in a process chamber.

FIG. 12 is a cross-sectional view taken along a horizontal plane illustrating a part of the top plate according to Example 3.

FIG. 13 is an enlarged partial cross-sectional view illustrating a vicinity of the top plate in a process chamber according to Example 4.

FIG. 14 is a partial enlarged cross-sectional view illustrating a vicinity of the top plate in a process chamber according to a first modified example of Example 4.

FIG. 15 is a partial enlarged cross-sectional view illustrating a vicinity of the top plate in a process chamber according to a second modified example of Example 4.

FIG. 16 is a partial enlarged cross-sectional view illustrating a vicinity of the top plate in a process chamber according to Example 5.

FIG. 17A illustrates a modified example of gas conduit arrangement.

FIG. 17B illustrates another modified example of gas conduit arrangement.

FIG. 18A is another modified example of gas conduit arrangement illustrated in FIG. 17A.

FIG. 18B is another modified example of gas conduit arrangement illustrated in FIG. 17B.

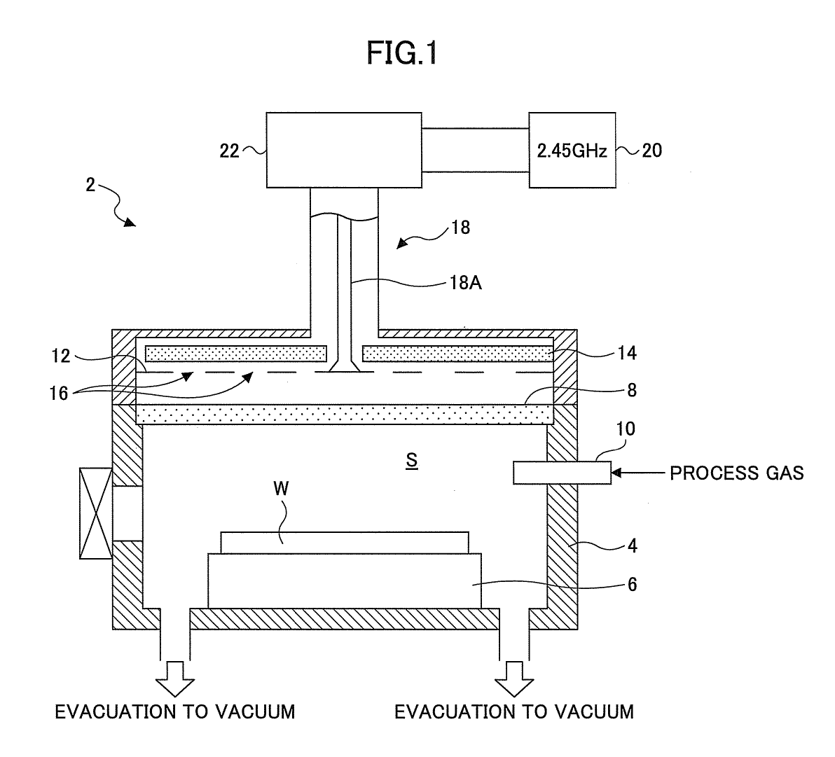

### DESCRIPTION OF THE REFERENCE SYMBOLS

32 plasma process apparatus
34 process chamber
36 susceptor
56 resistive
74 top plate
78 electromagnetic wave introduction portion
80 planar antenna member
84 slot
102, 102A, 102B, 102C, 102D, 102E, 102F gas conduit
103 gas inlet
104 gas ejection hole
108 porous dielectric body
114 gas introduction port
116 gas supplying portion
118 gas introduction conduit
W semiconductor wafer (object to be processed)

### MODE(S) FOR CARRYING OUT THE INVENTION

Referring to the accompanying drawings, a top plate and a plasma process apparatus employing the same according to an example of the present invention are explained.

### Example 1

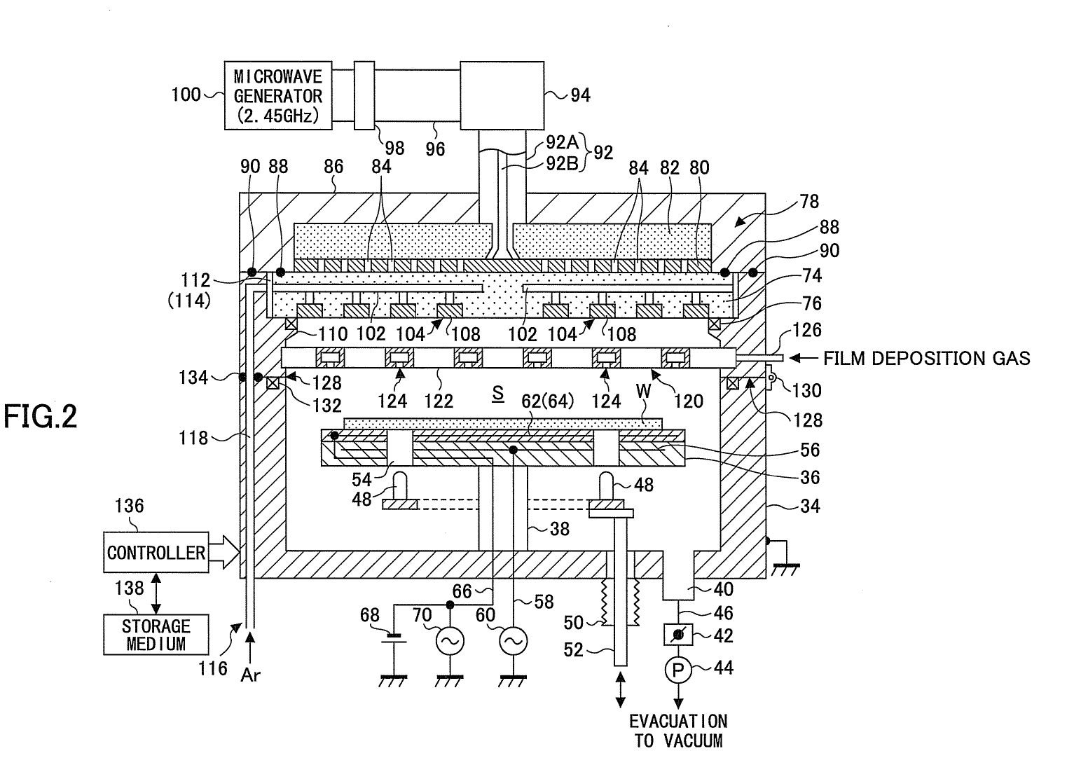

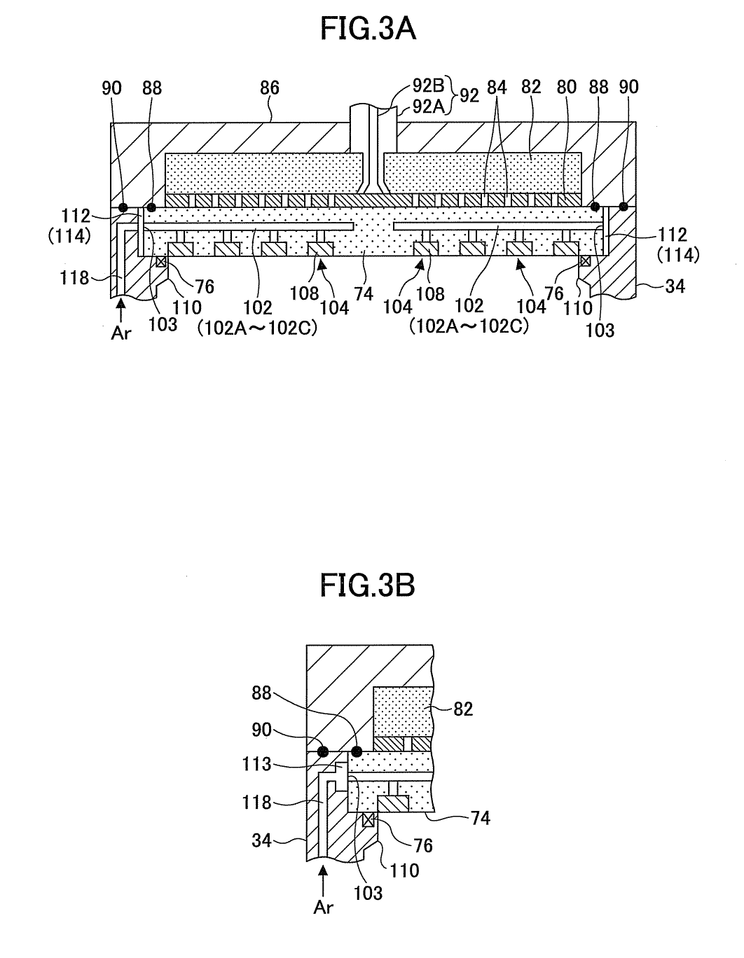

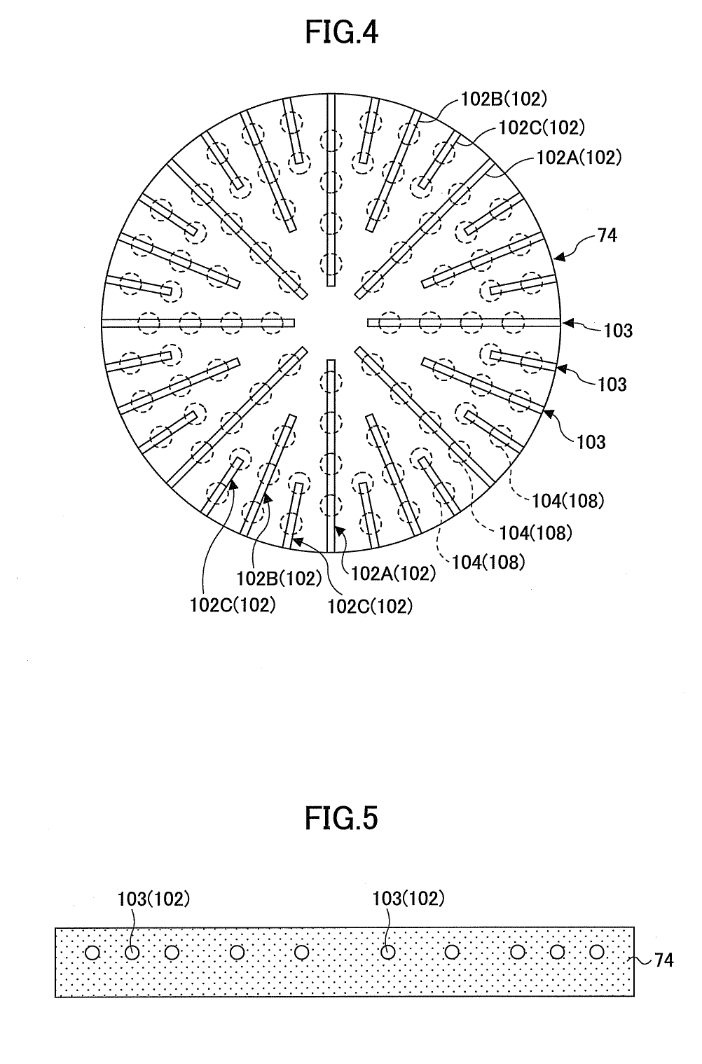

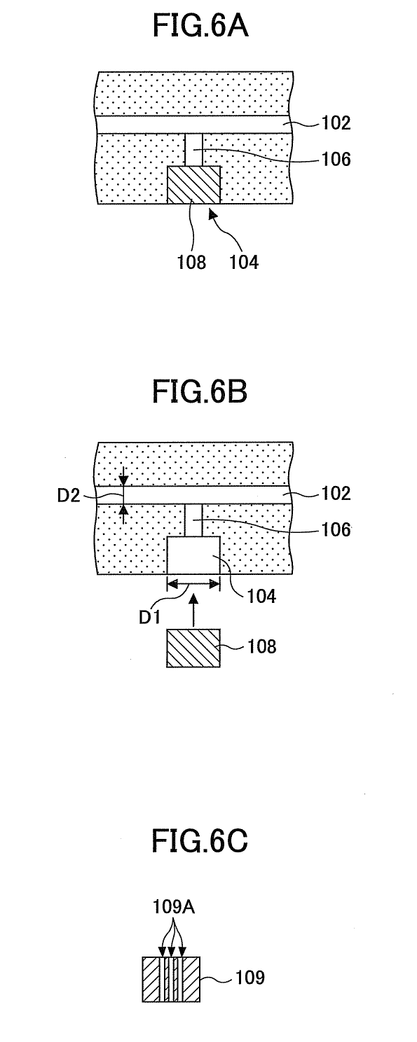

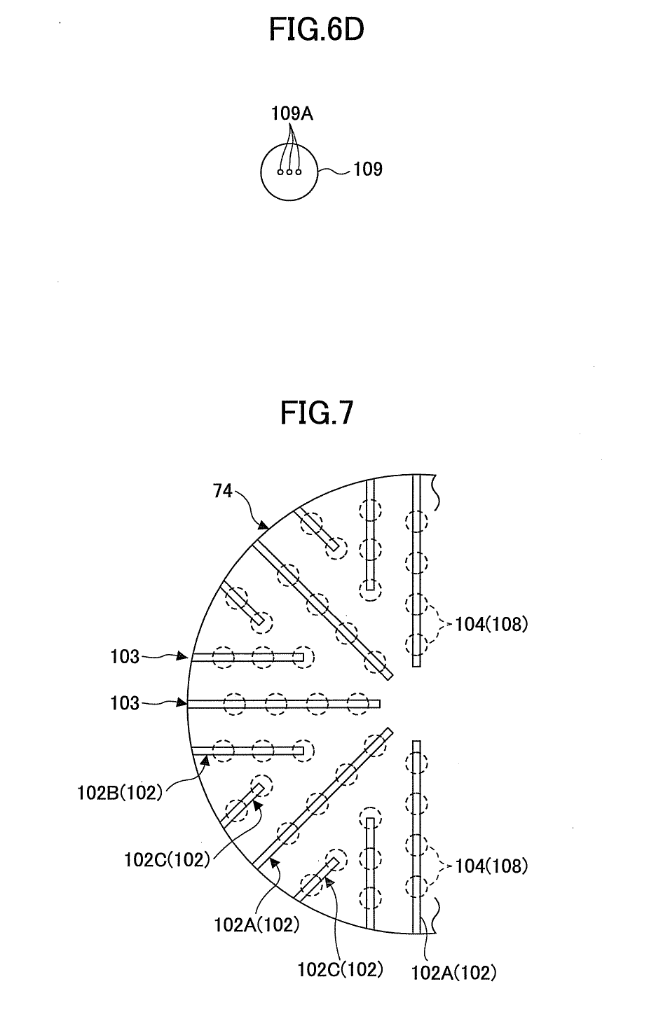

FIG. 2 is a schematic diagram illustrating a plasma process apparatus employing a top plate according to a first example of the present invention; FIG. 3A is an enlarged cross-sectional view illustrating the top plate and portions around the top plate in the plasma process apparatus; FIG. 4 is a cross-sectional view taken along a horizontal plane, illustrating gas conduits in the top plate; FIG. 5 is a side view of the top plate; and FIG. 6 is a cross-sectional view illustrating a partial configuration of gas ejection holes. FIG. 3B illustrates a modified example of the top plate according to the first example, described later.

A plasma process apparatus 32 includes a process chamber 34 whose sidewall and bottom portion are made of, for example, aluminum alloy or the like and has a cylindrical shape as a whole. A hermetically closed process space S is defined inside the process chamber 34, and plasma is generated in the process space S. In addition, the process chamber 34 is connected to ground in the illustrated example.

A susceptor 36 on which a semiconductor wafer W, for example, as an object to be processed is accommodated in the process chamber 34. The susceptor 36 has a flat disk-like shape and is made of, for example, ceramic materials such as alumina. The susceptor 36 is supported by a pillar 38 that is made of alumina and the like and rises from the bottom portion of the process chamber 36.

An opening (not shown) through which the wafer passes when the wafer is transferred into/out from the process chamber 34 and a gate valve (not shown) that is attached for the opening in order to open and close the opening are provided on the sidewall of the process chamber 34. In addition, an evacuation opening 40 is provided in the bottom portion, and an evacuation line 46 including a pressure control valve 42 and a vacuum pump 44 is connected to the evacuation opening 40. With these configurations, the process chamber 34 may be evacuated and the inside of the process chamber 34 may be maintained at a predetermined pressure, as necessary.

In addition, plural (for example, three) lift pins 48 (only two lift pins are illustrated in FIG. 2) for bringing the wafer W upward and downward when transferring the wafer W into/out from the process chamber 34 are provided below the susceptor 36. These lift pins 48 are moved upward and downward by an elevation rod 52 extending through a through hole formed in the bottom portion of the process chamber 34. The elevation rod 52 is hermetically attached to the bottom portion of the process chamber 34 via an extensible bellows 50. In addition, pin through holes 54 that allow the lift pins 48 to pass therethrough are formed in the susceptor 36. The susceptor 36 is made of materials resistant to an increased temperature, such as ceramic materials including alumina, as a whole. A resistive heater 56 having a thin plate shape, for example, is embedded inside the susceptor 36, in order to heat the wafer W placed on the susceptor 36. The resistive heater 56 is connected to a heater power supply 60 via an electric wire 58 passing through the pillar 38.

In addition, a thin electrostatic chuck 62 including conductive lines 64 arranged therein in a grid pattern is provided in an upper surface side of the susceptor 36, which makes it possible to hold the wafer placed on the susceptor 36, or the electrostatic chuck 62, by electrostatic suction force. The conductive lines 64 of the electrostatic chuck 62 are connected to a direct current power source 68 via an electric wire 66. In addition, a high frequency bias power source 70 for applying high frequency bias power of, for example, 13.56 MHz to the conductive lines 64 of the electrostatic chuck 62, if necessary, is connected to the electric wire 66. Incidentally, the high frequency bias power source 70 is not used depending on processes.

The process chamber 34 has an upper opening to which a top plate 74 is provided. The top plate 74 is made of, for example, quartz and ceramic materials such as Al2O3, and hermetically attached to the opening via a sealing member 76 placed along a circumferential direction on an upper brim surface of the opening. The top plate 74 may have a thickness of, for example, about 20 mm, taking into consideration pressure resistance. In addition, the top plate 74 serves as a showerhead for introducing gas. A configuration of the top plate 74 is described in detail below.

An electromagnetic wave introduction portion 78 for introducing electromagnetic waves for generating plasma into the process chamber 34 through the top plate 74 in order to generate plasma inside the process chamber 34 is provided on the top plate 74. Microwaves are used here as the electromagnetic waves. Specifically, the electromagnetic wave introduction portion 78 includes a disk-shaped planar antenna member 80 arranged on an upper surface of the top plate 74, and a slow wave structure 82 arranged on the planar antenna member 80. The slow wave structure 82 is made of, for example, ceramic materials such as aluminum nitride, and has a high dielectric constant in order to shorten a wavelength of the microwaves.

The planar antenna member 80 has a diameter of about 400 mm through about 500 mm and a thickness of about 1 mm through several millimeters, when a wafer having a diameter of about 300 mm is to be processed in the process chamber 34, and is made of, for example, an aluminum plate or a copper plate whose surface is electroplated with silver. Plural slots 84 having a shape of an oblong groove are formed in the planar antenna member 80. An arrangement of the slots 84 is not limited. For example, the slots 84 may be arranged in a concentric, a spiral, or a radial pattern. In addition the slots 84 are evenly arranged throughout the planar antenna member 80. The planar antenna member 80 has a configuration of a so-called Radial Line Slot Antenna (RLSA), which can generate high density and low electron temperature plasma in the process chamber 34.

A shield cover 86 for shielding the microwaves is provided in order to cover the planar antenna member 80 and the slow wave structure 82. A circumference of the shield cover 86 extends downward to form a sidewall. A lower end portion of the sidewall of the shield cover 86 is placed on an upper surface of the top plate 74 and an upper end portion of the process chamber 34. In order to hermetically maintain the process chamber 34, a sealing member 88 extending circumferentially in a ring shape is provided between the shield cover 86 and the top plate 74, and a sealing member 90 extending outside of and concentrically to the sealing member 88 is provided between the shield cover 86 and the process chamber 34. The sealing members 88, 90 may be O-rings, for example.

In addition, an outer conductive body 92A of a co-axial waveguide pipe 92 is connected to a central upper portion of the shield cover 86. An inner conductive body 92B of the co-axial waveguide pipe 92 is connected to a central portion of the planar antenna member 80. The co-axial waveguide pipe 92 is connected to a rectangular waveguide pipe 96 via a mode converter 94. The rectangular waveguide pipe 96 has in its middle a matching circuit 98, and is connected to a microwave generator 100 that generates microwaves of, for example, 2.45 GHz. With these configurations, the microwaves are transmitted to the planar antenna member 80. Namely, the microwave generator 100 and the planar antenna member 80 are connected with the rectangular waveguide pipe 96 and the co-axial waveguide pipe 92, and thus the microwaves are transmitted from the microwave generator 100 to the planar antenna member 80. Here, a frequency of the microwaves is not limited to 2.45 GHz, but the microwaves may have other frequencies, for example, 8.35 GHz.

Next, the top plate 74 is explained in detail. The top plate 74 is made of dielectric materials such as quartz and ceramic materials including Al2O3 or the like, as stated above, and has a solid disk shape, as shown in FIGS. 3 through 6. The top plate 74 includes plural gas conduits 102 formed along horizontal directions of the top plate 74, and plural gas ejection holes 104 that are in gaseous communication with the gas conduits 102 and formed in a plane of the top plate 74 facing the inside of the process chamber 34.

Specifically, each of the gas conduits 102 has an opening at one end in a side surface of the top plate 74 and extends toward the center portion of the top plate 74. Therefore, the gas conduits 102 are arranged in radial directions as a whole, as shown in FIG. 4. In addition, the gas conduits 102 are arranged at equal angular intervals along a circumferential direction of the top plate 74. The gas conduits 102 are independent, without being in gaseous communication with one another. The opening of each of the gas conduits 102 in the side surface of the top plate 74 serves as a gas inlet 103 (see FIG. 5) for introducing gas into the gas conduit 102. As shown in FIG. 4, there are three types of gas conduits 102 depending on their lengths. Namely, there are long gas conduits 102A, short gas conduits 102C, and middle length gas conduits 102B. The gas conduits 102 are arranged in an order of the gas conduit 102A, the gas conduit 102C, the gas conduit 102B, the gas conduit 102C, the gas conduit 102A, . . . , in the circumferential direction of the top plate 74. Here, the long gas conduit 102A extends to a vicinity of the center portion of the top plate 74 and can supply the gas to the process chamber 34.

In addition, the top plate 74 is provided with the plural gas ejection holes 104 arranged at predetermined intervals along the longitudinal direction of each of the gas conduits 102. Specifically, four gas ejection holes 104 are formed along the long gas conduit 102A; three gas ejection holes 104 are formed along the middle length gas conduit 102B; and two gas ejection holes 104 are formed along the short gas conduit 102C, as shown in FIG. 4. In such a manner, the gas ejection holes 104 are substantially uniformly arranged on a gas ejection surface or lower surface of the top plate 74. The gas ejection holes 104 are connected to the gas conduits 102 via connection passages 106 (see FIG. 6A). In addition, a porous dielectric body 108 having an aeration property is mounted into each of the gas ejection holes 104, which may allow the gas to flow into the process chamber 34 and reduce abnormal electric discharge that may be caused by the microwaves. Incidentally, FIG. 6B illustrates the gas ejection hole 104 and the porous dielectric body 108 that has not yet been mounted into the gas ejection hole 104.

Here, sizes of each of the portions are exemplified. A diameter D1 (see FIG. 6B) of the gas ejection hole 104 may be half that of a wavelength λ0 of the electromagnetic waves (microwaves) propagating through the top plate 74, and within, for example, a range from about one mm through about 35 mm. If the diameter D1 is greater than half that of the wavelength λ0, relative permittivity becomes greatly different in a portion corresponding to the gas ejection hole 104, and as a result, electric field density in the portion is different from that in different portions, which unfavorably leads to non-uniform plasma density.

In addition, diameters of voids included in the porous dielectric body 108 may be less than or equal to about 0.1 mm. When the diameter is greater than 0.1 mm, a probability of abnormal electric discharge of plasma may be increased. Incidentally, there are countless numbers of voids continuously arranged in the porous dielectric body 108, so that the aeration property is maintained.

Moreover, a diameter D2 of each of the gas conduits 102 may be as small as possible, as long as gas flow is not impeded, and may be determined to be smaller than the diameter D1 of the gas ejection hole 104, in order not to adversely influence the microwaves or electric field distribution. Incidentally, a ceramic member 109 having fine holes as shown in FIGS. 6C and 6D may be used in the place of the porous dielectric body 108. FIG. 6C is a cross-sectional view of the ceramic member 109, and FIG. 6D is a plan view of the ceramic member 109. Inside the ceramic member 109, gas discharge holes 109 having a diameter of about 0.05 mm are provided as the fine holes. While there are three gas discharge holes 109 in the drawing, the number of the gas discharge holes 109 is not limited. It is preferable that as many gas discharge holes 109A as possible are formed in order to increase an amount of gas to be discharged and reduce a discharge speed of the gas.

<Manufacturing Method of the Top Plate>

Next, a manufacturing method of the top plate 74 is explained. When the top plate 74 is formed of quartz, first, a disk-shaped quartz plate as a mother material is prepared, and a process is carried out where the gas conduits 102 (102A through 102C) shown in FIG. 4 are formed (perforated) in a radial pattern from a side surface of the quarts plate using a drill, laser beam, or the like.

Next, a process is carried out where the connection passages 106 and the gas ejection holes 104 are formed (perforated) as shown in FIG. 6 B in this order using a drill, laser beam, or the like. Incidentally, after the connection passages 106 and the gas ejection holes 104 are formed, the gas conduits 102 may be formed.

Then, the porous dielectric bodies 108 that have been made in advance by sintering are mounted into the gas ejection holes 104. The porous dielectric bodies 108 are mounted into the gas ejection holes 104 under high temperature. With these, the top plate 74 is finished.

When the top plate 74 is formed of ceramic material such as alumina, first, a process is carried out where the gas conduits 102 (102A through 102C), as shown in FIG. 4, are formed (perforated) in a disk-shaped half-finished product, which is a mother material for the top plate 74 using a drill, laser beam, or the like. Here, as the half-finished product, a cast body (also referred to as a green body) obtained by press-working pelletized powders into a circular plate, the pelletized powders being obtained by spray-drying a binder material with Al₂O₃ raw material powders, a degreased body obtained by sintering the cast body at about 400° C., and a provisionally sintered body obtained by sintering the green body at about 1000° C. may be used.

Next, a process is carried out where the connection passages 106 and the gas ejection holes 104 are formed (perforated) in one surface of the half-finished product in this order using a drill, laser beam, or the like. Incidentally, after the connection passages 106 and the gas ejection holes 104 are formed, the gas conduits 102 may be formed.

Next, the porous dielectric bodies 108 that have not yet been sintered and whose sintering shrinkage rate is slightly smaller than that of the half-finished product of the green body, the degreased body, or the provisionally sintered body of the top plate 74 are mounted into the gas ejection holes 104.

After the pre-sintered porous dielectric bodies 108 are mounted into the gas ejection holes 104, the half-finished product as a whole is fully sintered at a high temperature of, for example, 1450° C. With this, the top plate 74 is finished.

Referring back to FIG. 2 or FIG. 3, the top plate 74 formed in the above manner is hermetically attached on an attachment step portion 110 provided in a vicinity of the opening of the ceiling portion of the process chamber 34 via a sealing member 76. In this case, an inner diameter of the sidewall of the process chamber 34 in a vicinity of the ceiling portion thereof is slightly larger than a diameter of the top plate 74 in order to easily attach and remove the top plate 74. A gap 112 between the sidewall and the top plate 74 serves as a gas inlet port 114, which is formed along the circumferential direction of the top plate 73 in a ring shape.

Incidentally, when the diameter of the top plate 74 is substantially the same as the inner diameter of the sidewall of the process chamber 34 in a vicinity the ceiling portion thereof and thus there is no gap 112, a gas inlet groove 113 may be formed along an inner circumferential portion of the sidewall of the process chamber 34 in a vicinity of the ceiling portion thereof, in the place of the gap 112 (gas inlet port 114), as shown in FIG. 35. With this, positioning accuracy of the top plate 74 integrated to the process chamber 34 can be improved. Such a configuration with the gas inlet groove 113 may be applied to all the examples explained hereinafter.

A gas supplying portion 116 for supplying the gas is connected to the gas inlet port 114. Specifically, the gas supplying portion 116 includes a gas conduit 118 formed along a height direction in the sidewall of the process chamber 34, and a distal end of the gas introduction conduit 118 is in communication with the gas inlet port 114. The above-mentioned sealing members 88, 90 are provided in order not to allow the gas to leak from the gas inlet port 114 to the exterior. The gas introduction conduit 118 includes in its middle a flow controller such as a mass flow controller (not shown), which make it possible to supply, for example, an inert gas for plasma excitation such as Ar gas at a controlled flow rate.

Inside the process space S, there is provided another gas inlet portion 120. Specifically, the gas inlet portion 120 has a so-called showerhead structure where pipes 122 made of quartz, aluminum alloy, or the like are arranged, for example, in a grid pattern, and plural gas ejection holes 124 are formed in a lower surface of the grid-patterned pipes 122. A gas conduit 126 having in its middle a flow rate controller (not shown) is connected to the gas inlet portion 120, which makes it possible to supply a necessary gas (process gas), for example, a film deposition gas in the case of a film deposition process at a controlled flow rate. Incidentally, the gas inlet portion 120 may be provided, when necessary, depending on processes.

In addition, the process chamber 34 is separatable vertically into two parts at a separation line 128 slightly below the gas inlet portion 120 (see FIG. 2). A hinge 130 is provided to straddle the separation line 128. With this, the upper part of the process chamber 34 may be open around the hinge 130 for the purpose of maintenance or the like. Therefore, a large diameter sealing member 132 such as an O-ring is provided in a position corresponding to the separation line 128 in order to maintain air-tightness of the process chamber 34. In addition, a small diameter sealing member 134 such as an O-ring is provided in a separatable portion of the gas introduction conduit 118 of the gas supplying portion 116 so that the sealing member 134 surrounds the gas introduction conduit 118.

Entire operations of the plasma process apparatus 32 configured as above are controlled by a control portion 136 composed of, for example, a computer, and computer programs for carrying out the operations are stored in a storage medium 138 such as a floppy disk, a Compact Disc (CD), a flash memory, a hard disk, or the like. Specifically, supplying the gases, controlling flow rates of the gases, supplying the microwaves or high frequency waves, supplying electric power, controlling a process temperature and a process pressure, and the like are controlled by instructions from the control portion 136.

Next, a film deposition method that may be carried out using the plasma process apparatus 32 configured as above is explained.

First, the semiconductor wafer W is transferred into the process chamber 34 through the gate valve (not shown), placed on the susceptor 36 by bringing the lift pins 48 upward and downward, and electrostatically held by the electrostatic chuck 64. The wafer W is maintained at a predetermined temperature by the resistive heater 56. A deposition gas is ejected from the gas ejection holes 124 of the gas inlet portion 120 arranged in the process chamber 34 at a controlled flow rate into the process space S, and Ar gas is ejected from the gas ejection holes 104 formed in the top plate through the porous dielectric body 108 having an aeration property into the process space S. In addition, the process chamber 34 is maintained at a predetermined pressure by controlling the pressure control valve 42.

In addition, along with the above operations, the microwaves are generated by turning on the microwave generator 100 and the microwaves are supplied to the planar antenna member 80 via the rectangular waveguide pipe 96 and the co-axial waveguide pipe 92. With this, the microwaves whose wavelength is shortened by the slow wave structure 82 are introduced into the process space S, which generates plasma in the process space S, thereby carrying out the film deposition process utilizing the plasma.

When the microwaves are introduced into the process chamber 34 from the planar antenna member 80 in such a manner, the Ar gas is ionized into plasma and becomes activated. Along with this, the deposition gas is activated, and a thin film is formed on the upper surface of the wafer W by active species generated at this time. The gases substantially uniformly spread around the susceptor 36 and flow downward. Then, the gases are evacuated from the evacuation line 46 through the evacuation opening 40.

Here, supplying of the gas to the top plate 74, which also serves as the showerhead, is explained in detail. First, the Ar gas flowing at a controlled flow rate through the gas introduction conduit 118 of the gas supplying portion 116 flows into the gas inlet port 114 formed in a ring shape open along the outer circumferential surface of the top plate 74, and thus flows in the gas inlet port 114 along the circumferential direction of the top plate 74. The Ar gas, while flowing in the gas inlet port 114, flows into the gas conduits 102A through 102C through the gas inlet 103 formed in the sidewall of the top plate 74. Then, the Ar gas reaches the gas ejection holes 104 through the connection passages 106 (see FIG. 6) provided to be in gaseous communication with the gas conduits 102A through 102C, and is ejected into the process space S through the porous dielectric bodies 108 mounted into the gas ejection holes 104.

In this embodiment, because the top plate 74, which serves as the showerhead, is formed, as a solid part, of quartz or ceramic materials without employing a sealing member such as an O-ring or the like, the top plate 74 can have increased overall strength without an increase in thickness. Therefore, because durability of the top plate 74 against an increase in temperature can be enhanced, not only electric power of the microwaves supplied to the top plate 74 can be increased, but also a supplying pressure of the Ar gas can be increased while reducing chances of damage. Accordingly, a larger amount of the Ar gas corresponding to the increased supplying pressure can be supplied, thereby increasing production throughput.

In addition, because no sealing members are provided in the top plate 74, even when abnormal electric discharge takes place in the gas conduits 102A through 102C or the like, which may damage the sealing member such as an O-ring, the gas is substantially prevented from leaking.

### Modified Example of Example 1

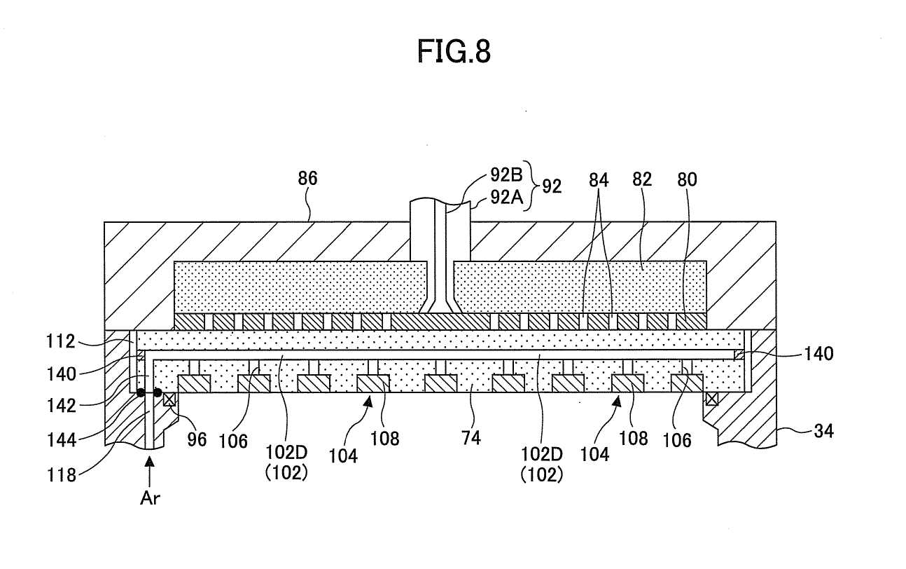

Next, a modified example of the top plate according to Example 1 of the present invention is explained. FIG. 7 is a cross-sectional view taken along a horizontal plane of the top plate, illustrating a part of the gas conduits of the top plate according to the modified example of Example 1 of the present invention. Because the top plate is formed symmetrically, substantially a half of the top plate is illustrated here. The same reference symbols are given to the same portions as those in the top plate according to the previous example. In addition, the cross-section of the top plate according to the modified example of Example 1 is illustrated in the same manner as that of the top plate of Example 1 illustrated in FIG. 3.

The top plate 74 according to the modified example of Example 1 includes the gas conduits 102 formed toward the center of the top plate 74 in a radial pattern, and other gas conduits 102 arranged in parallel with the gas conduits 102 formed in the radial pattern.

Specifically, the long gas conduits 102A extend in a radius direction to a vicinity of the center of the top plate 74, and are arranged in a radial pattern as a whole. On both sides of one of the long gas conduits 102A, the short gas conduits 102C are arranged in parallel with the one of the long gas conduits 102A, and on both sides of another long gas conduit 102A nearest to the one of the long gas conduits 102A, the middle length gas conduits 102E are arranged in parallel with the another long gas conduit 102A. In such a manner, the gas conduits 102 are arranged in an order of the gas conduit 102A, the gas conduit 102B, the gas conduit 102C, the gas conduit 102A, the gas conduit 102C, the gas conduit 102B, the gas conduit 102A . . . , in the circumferential direction of the top plate 74. Even in this case, each of the gas conduits 102 is independent, without being in gaseous communication with one another. Two to four gas ejection holes 104 are formed in the gas conduits 102A through 102C, and the porous dielectric bodies 108 are mounted into the gas ejection holes 104.

The top plate 74 according to the modified example can demonstrate the same effect as the top plate according to Example 1 shown in FIGS. 3 and 4. Incidentally, the number of the gas conduits 102 and the number of the gas ejection holes 104 are merely exemplified in Example 1 and its modified example, and not limited to the above numbers.

### Example 2

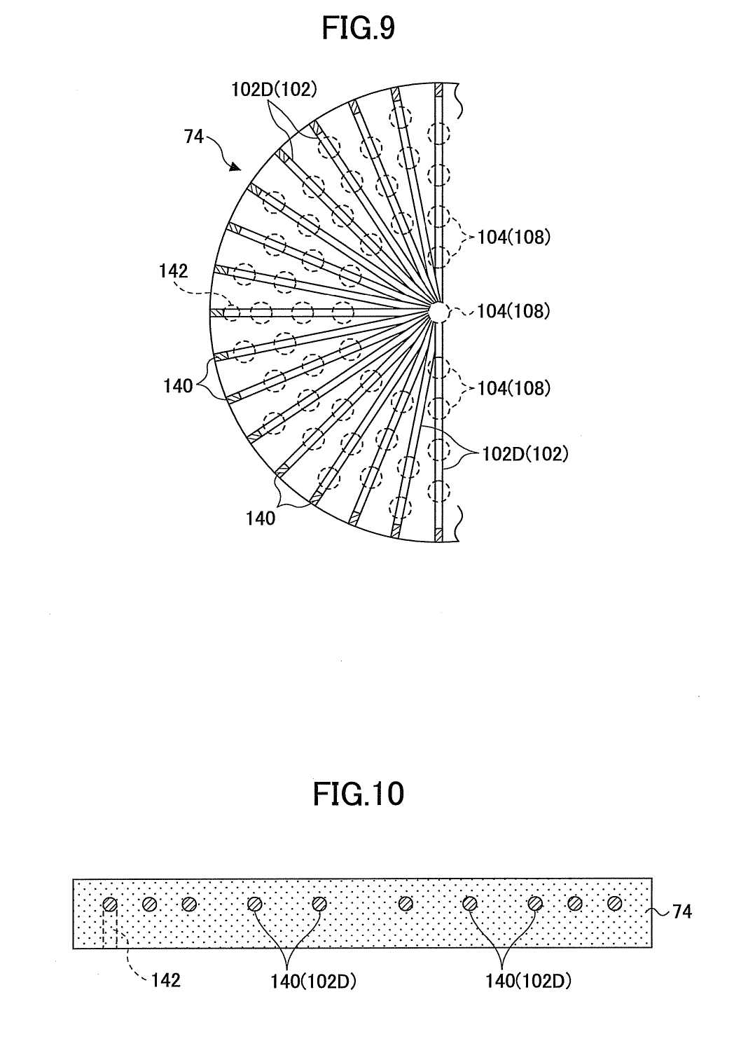

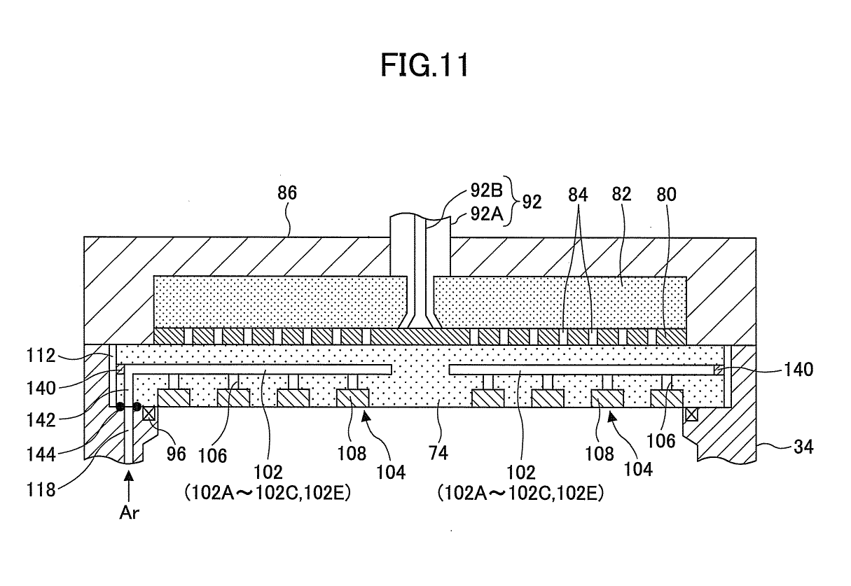

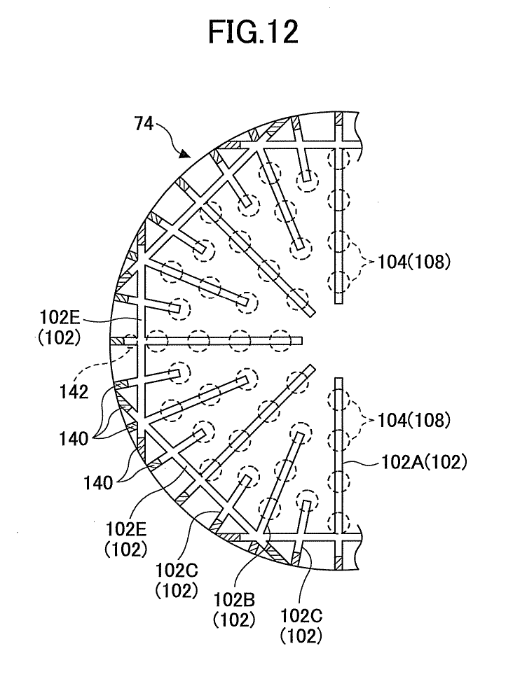

Next, a top plate according to Example 2 is explained. FIG. 8 is a partial enlarged cross-sectional view illustrating a vicinity of the top plate according to Example 2; FIG. 9 is a cross-sectional view illustrating a part of the top plate according to Example 2, taken along a horizontal plane; and FIG. 10 is a side view of the top plate according to Example 2.

Incidentally, FIG. 9 illustrates substantially a half of the top plate because the top plate is formed symmetrically. In addition, the same reference symbols are given to the same parts as those in the previous examples.

As shown in FIG. 9, gas conduits 102D are formed in order to extend to a vicinity of the center portion of the top plate 74, and are in gaseous communication with one another in the center portion, in the case of Example 2. Therefore, the gas conduits 102D are provided in a radial pattern from the center portion of the top plate 74.

The gas ejection holes 104 are formed in the top plate 74 in order to be in gaseous communication with the corresponding gas conduits 102D at predetermined intervals, and the porous dielectric bodies 108 are mounted into the gas ejection holes 104. In this case, the same number of the gas ejection holes 104 is not formed in the gas conduits 102D, but the number of the gas ejection holes 104 per one gas conduit 102D is arbitrarily varied in order to uniformly distribute the gas in the top plate 74. Incidentally, one of the gas ejection holes 104 into which the corresponding porous dielectric body 108 is mounted is formed in the center portion of the top plate 74.

As shown in FIG. 10, the openings 103 of the gas conduits 102D open on the outer circumferential surface of the top plate 74 are closed with sealing materials 140. In addition, a gas inlet 142 that is in gaseous communication with at least one of the gas conduits 102D and is open at the lower surface of the top plate 74 is formed in a vicinity of the outer circumference of the top plate 74. The gas inlet 142 is in alignment with an upper end of the gas introduction conduit 118 of the gas supplying portion 116, and thus is in gaseous communication with the gas introduction conduit 118. Incidentally, plural gas inlets 142 may be formed in order to be in gaseous communication with the plural gas conduits 102D. A sealing member 144 (FIG. 8) such as an O-ring or the like is provided around the gas introduction conduit 118 and the gas inlet 142 in a connection portion of the gas introduction conduit 118 and the gas inlet 142, which substantially prevents gas leakage.

In this case, because no gas flows into the gap 112 between the outer circumferential surface of the top plate 74 and the inner wall of the upper portion of the process chamber 34, the sealing members 88, 90 (see FIG. 2) that are provided above the gas 112 in Example 1 need not to be provided.

In addition, in the case of Example 2, the Ar gas flowing into the one of the gas conduits 102D through the gas inlet 142 flows to the center portion of the top plate 74, and further flows into the other gas conduits 102D in a radial pattern.

Even in this case, the same effect as explained in Example 1 can be demonstrated. In addition, the two sealing members 88, 90, which are provided to the shield cover 86 and have relatively large diameters, are not necessary in Example 2, which leads to a cost reduction of the sealing members.

In addition, the sealing member 144 provided in the connection portion of the gas introduction conduit 118 and the gas inlet 142 is very small and can be set only by bringing the top plate 74 downward, which enables easy positioning of the sealing member 144, thereby facilitating assembling at the time of maintenance.

Incidentally, the sealing materials 140 may be attached to end portions of the gas conduits 102D by sintering during production of the top plate 74 (or at the time when the top plate 74 remains as a half-finished product), or after the top plate 74 is finished. In addition, the gas inlet 142 may be formed in order to be open on the upper surface of the top plate 74, and the gas introduction conduit 118 may be connected thereto from above.

### Example 3

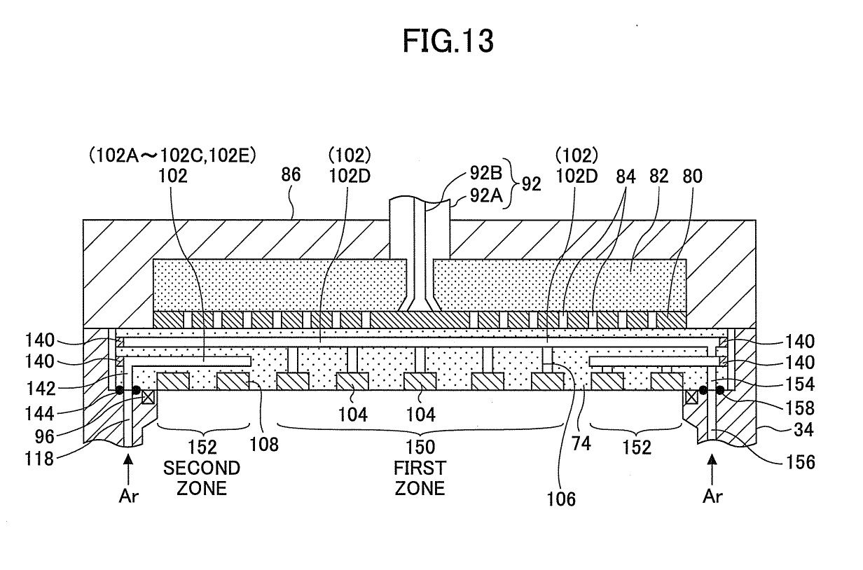

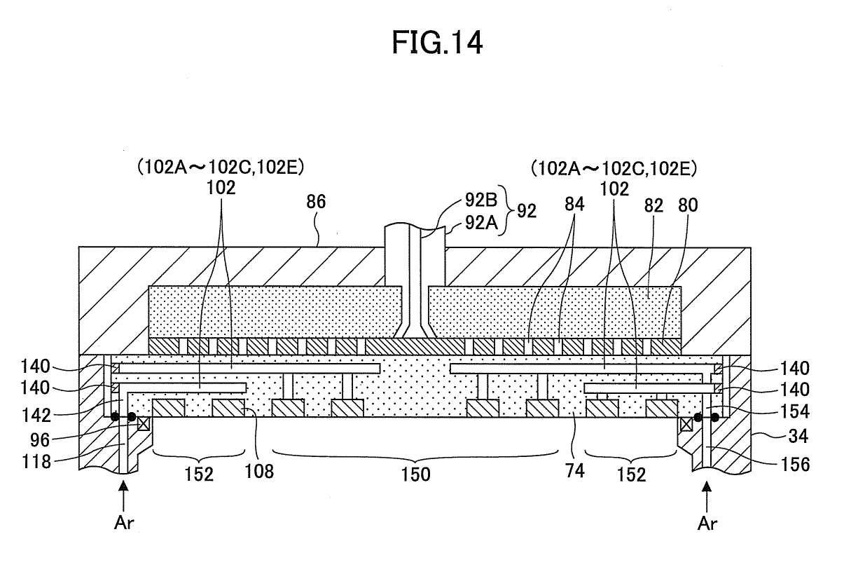

Next, a top plate according to Example 3 is explained. FIG. 11 is a partial enlarged cross-sectional view illustrating a vicinity of the top plate in a process chamber; and FIG. 12 is a cross-sectional view taken along a horizontal plane illustrating a part of the top plate according to Example 3. Incidentally, because the top plate is formed symmetrically, substantially a half of the top plate is illustrated in FIG. 12. The same reference symbols are given to the same portions as those in the previous examples.

In the case of Example 3, the top plate 74 includes the gas conduits 102A through 102C arranged in the same manner as in Example 1 illustrated in FIG. 4, and gas conduits 102E that intersect and are in gaseous communication with at least one of the gas conduits 102A through 102C. In the illustrated example, the gas conduits 102E are in gaseous communication with all the gas conduits 102A through 102C.

In addition, the gas ejection holes 104 are formed to be in gaseous communication with the gas conduits 102A through 102C via the connection passages 106 (FIG. 11) in the top plate 74. The porous dielectric bodies 108 are mounted into the gas ejection holes 104. Incidentally, the gas ejection holes 104 into which the porous dielectric bodies 108 may be mounted may be provided to the gas conduits 102E. Moreover, the openings of the gas conduits 102A through 102C and 102E which are open on the circumferential surface of the top plate 74 are closed with the sealing materials 140.

Furthermore, the gas inlet 142 that is in gaseous communication with at least one of the gas conduits 102A through 102C and is open on the lower surface of the top plate 74 is formed in a vicinity of the outer circumferential surface of the top plate 74, as shown in FIG. 11. The gas inlet 142 is in alignment with the upper end of the gas introduction conduit 118, and thus is in gaseous communication with the gas introduction conduit 118. With this configuration, the gas flows into the gas conduits 102A through 102C through the gas inlet 142, rather than through the openings of the gas conduits 102A through 102C and 102E which are open on the outer circumferential surface of the top plate 74, in the top plate 74 of this example. Incidentally, the sealing member 144 such as an O-ring is provided at the connection portion of the gas inlet 142 and the gas introduction conduit 118, thereby substantially preventing gas leakage.

Even in this case, because the Ar gas introduced into one of the gas conduits 102A through 102C and 102E from the gas introduction conduit 118 flows into the other gas conduits 102A through 102C and 102E, the same effect as explained in Example 2 can be demonstrated. Incidentally, the gas inlet 142 may be open on the upper surface of the top plate 74 in Example 3. In addition, the top plate 74 according to Example 3 may include the gas conduits 102A through 102C according to the modified example of Example 1 illustrated in FIG. 7 and the gas conduits 102E in gaseous communication with the gas conduits 102A through 102C, in the place of the gas conduits 102A through 102C according to Example 1 illustrated in FIG. 4.

### Example 4

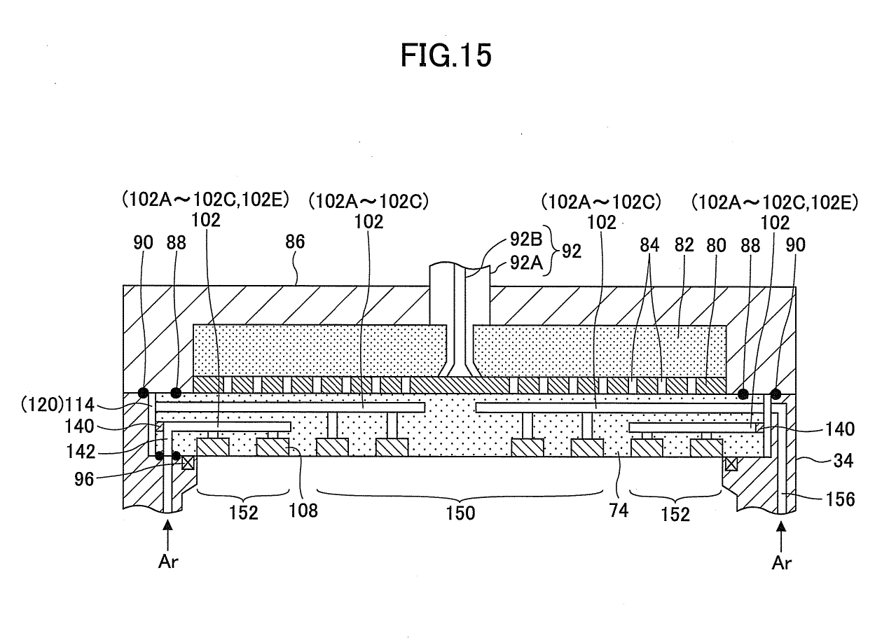

Next, a top plate according to Example 4 is explained. FIG. 13 is an enlarged partial cross-sectional view illustrating a vicinity of the top plate in a process chamber. The same reference symbols are given to the same portions as those in the previous examples.

While the top plate 74 according to the previous examples is configured so that the gas is ejected from the gas ejection holes 104 at a controlled flow rate, the top plate 74 according to Example 4 is configured so that the gas ejection holes 104 are grouped into plural zones, and a flow rate of the gas is controlled in each zone. Specifically, the gas ejection holes 104 are grouped into a first zone 150 located in an inner circle of the top plate 74 and a second zone 152 located in an outer portion of and concentrically to the first zone 150. The gas ejection holes 104 belonging to the first zone 150 are in gaseous communication with the gas conduits 102D that are arranged in a radial pattern to be in gaseous communication with one another at the center portion of the top plate 74, as explained in Example 2 illustrated in FIGS. 8 and 9.

In addition, a gas inlet 154 that is in gaseous communication with at least one of the gas conduits 102D and is open on the lower surface of the top plate 74 is formed in a vicinity of the outer circumferential surface of the top plate 74, as illustrated in a right hand portion of FIG. 13. The gas inlet 154 is in alignment with an upper end of a gas introduction conduit 156, and thus is in gaseous communication with the gas introduction conduit 156. A sealing member 158 such as an O-ring is provided in a connection portion of the gas inlet 154 and the gas conduit 156, thereby substantially preventing gas leakage. Incidentally, the gas introduction conduit 156 constitutes the gas supplying portion 116 (see FIG. 2).

On the other hand, the gas ejection holes 104 belonging to the second zone 152 are in gaseous communication with the gas conduits 102A through 102C of a first group, which extend to the center portion of the top plate 74 as explained in Example 3 illustrated in FIGS. 11 and 12, and with the gas conduits 102E of a second group, which are in gaseous communication with the gas conduits 102A through 102C. Namely, the gas conduits 102A through 102C of the first group are in gaseous communication with the gas conduits 102E of the second group formed to traverse the gas conduits 102A through 102C. The gas conduits 102D of the first group are positioned at a different height from the height of the gas conduits 102A through 102C, 102E of the second group in a thickness direction of the top plate 74. Specifically, the gas conduits 102D of the first group are positioned higher than the gas conduits 102A through 102C, 102E of the second group. When the connection passages 106 in gaseous communication with the gas conduits 102D are located in the outer portion of the top plate 74, the connection passages 106 may interfere with the gas conduits 102A through 102C, 102E positioned below. For this reason, the connection passages 106 in gaseous communication with the upper gas conduits 102D are preferably provided in the inner portion of the top plate 74.

The top plate 74 according to Example 4 can demonstrate the same effect as the top plate 74 according to Examples 2 and 3. In addition, because the gas ejection holes 104 are grouped into the first zone 150 and the second zone 152 concentric to each other, the Ar gas can be ejected at controlled flow rates independently in the first and the second zones 150, 152.

### First Modified Example of Example 4

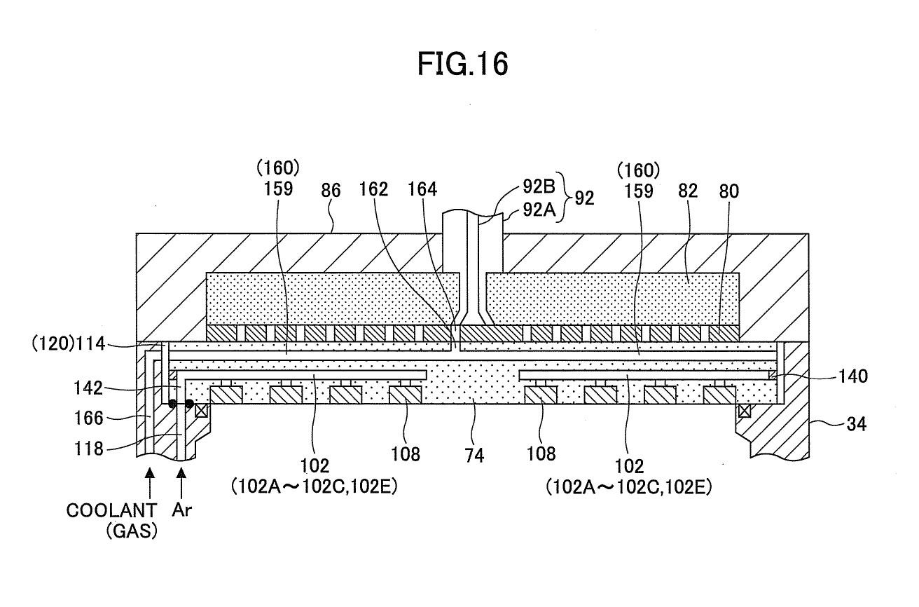

Next, a top plate according to a first modified example of Example 1 is explained. FIG. 14 is a partial enlarged cross-sectional view illustrating a vicinity of the top plate in a process chamber according to the first modified example of Example 4. The same reference symbols are given to the same portions as those in the previous examples.

While in Example 4 the gas ejection holes 104 belonging to the first zone 150 are in gaseous communication with the gas conduits 102D, which have been explained in Example 2, and the gas ejection holes 104 belonging to the second zone 152 are in gaseous communication with the gas conduits 102A through 102C, 102E, which have been explained in Example 3, the gas ejection holes 104 belonging to the first zone 150 may be in gaseous communication with the gas conduits 102A through 102C, 102E as shown in FIG. 14. Even in this case, the same effect explained in Example 4 can be demonstrated.

### Second Modified Example of Example 4

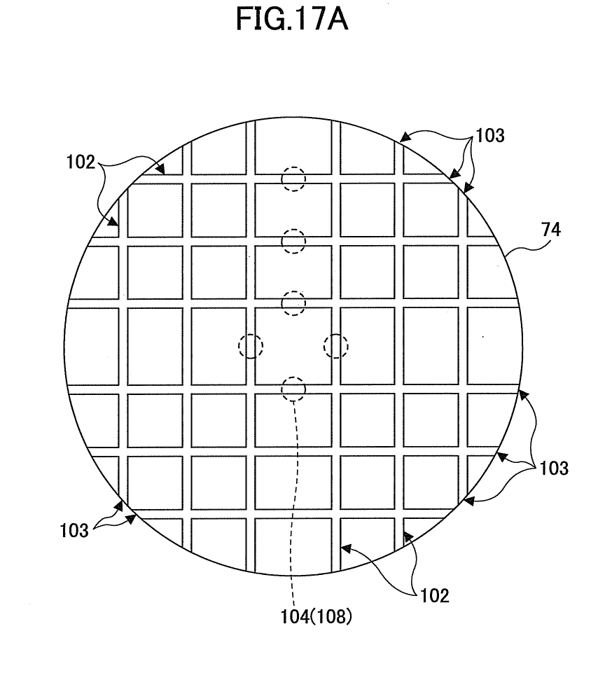

Next, a top plate according to a first modified example of Example 1 is explained. FIG. 15 is a partial enlarged cross-sectional view illustrating a vicinity of the top plate in a process chamber according to the second modified example of Example 4. The same reference symbols are given to the same portions as those in the previous examples.

While the gas ejection holes 104 belonging to the first zone 150 are in gaseous communication with the gas conduits 102D, which have been explained in Example 2, and the gas ejection holes 104 belonging to the second zone 152 are in gaseous communication with the gas conduits 102A through 102C, 102E, which have been explained in Example 3, in Example 4, the gas ejection holes 104 belonging to the first zone 150 may be in gaseous communication with the gas conduits 102A through 102C that have been explained in Example 1, or with the gas conduits 102A through 102C that have been explained in the modified example of Example 1.

Incidentally, in the second modified example of Example 4, the gas ejection holes 104 belonging to the first zone 150 may be in gaseous communication with the gas conduits 102A through 102C of Example 3, and the ejection holes 104 belonging to the second zone 152 may be in gaseous communication with the gas conduits 102A through 102C of Example 1 and the modified example of Example 1.

(Co-Existence with a Cooling Portion)

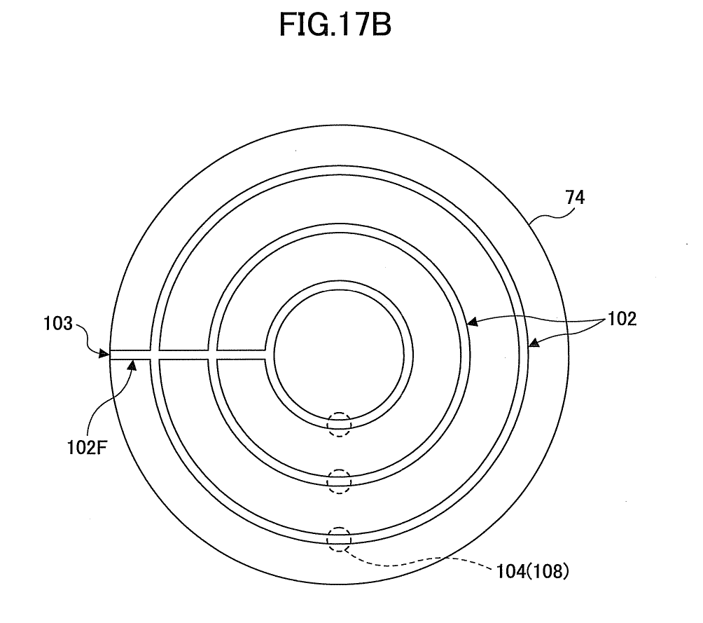

Next, a top plate according to a fifth example of the present invention is explained. FIG. 16 is a partial enlarged cross-sectional view illustrating a vicinity of the top plate in a process chamber according to Example 5. The same reference symbols are given to the same portions as those in the previous examples.

The top plate 74 according to Example 5 is provided with a cooling portion 159. Specifically, coolant passages 160 for cooling the top plate 74 by allowing a coolant to flow therethrough are provided in the top plate 74. Referring to FIG. 16, the gas conduits 102A through 102C, 102E of Example 3 illustrated in FIGS. 11 and 12 are provided and the coolant passages 160 are provided above the gas conduits 102A through 102C, 102E.

The coolant passages 160 are provided in a radial pattern, in the same manner as the gas conduits 102D of Example 2 illustrated in FIGS. 8 and 9, and in fluid communication with one another in the center portion of the top plated 74. In addition, gas holes 162, 164 extending upward from the coolant passages 160 are provided in the center portions of the top plate 74 and the planar antenna member 80, respectively. With these configurations, the coolant flowing through the coolant passages 160 can be evacuated toward an upper portion of the co-axial waveguide pipe 92 from the hole made in the slow wave structure 82.

In addition, openings of the coolant passages 160 which are open on the outer circumferential surface of the top plate 74 are in fluid communication with the gas introduction port 114, which is connected to a coolant introduction passage 166 extending from below in the sidewall of the process chamber 34. With this, a coolant can be supplied to the coolant passages 160. Here, the coolant may be cooled clean air, nitrogen gas, or the like. In this case, because such coolants do not cause a serious problem even when the coolants are leaked into the atmosphere, sealing members such as the sealing members 88, 90 (see FIG. 2) above the gas introduction port 114 (or the gap 112) are not necessary.

In the case of Example 5, the coolant supplied to the coolant introduction passage 166 flows along the circumferential direction in the gas inlet port 14, and further into each of the coolant passages 160. Then, the coolant flows to the center portion of the top plate 74 while cooling the top plate 74, and toward the co-axial waveguide pipe 92 through the gas holes 162, 164, and is released into the atmosphere. In such a manner, the top plate 74 can be cooled by the coolant flowing through the coolant passages 160, thereby preventing a temperature of the top plate 74 from being excessively increased.

The coolant passages 160 arranged in a radial pattern and the gas hole 162 may be formed (perforated) using a drill, laser beam, or the like in the same manner when the gas conduits 102 are formed. In addition, the cooling portion 159 may be provided in the top plate 74 according to Examples 2 through 4 (including the modified examples).

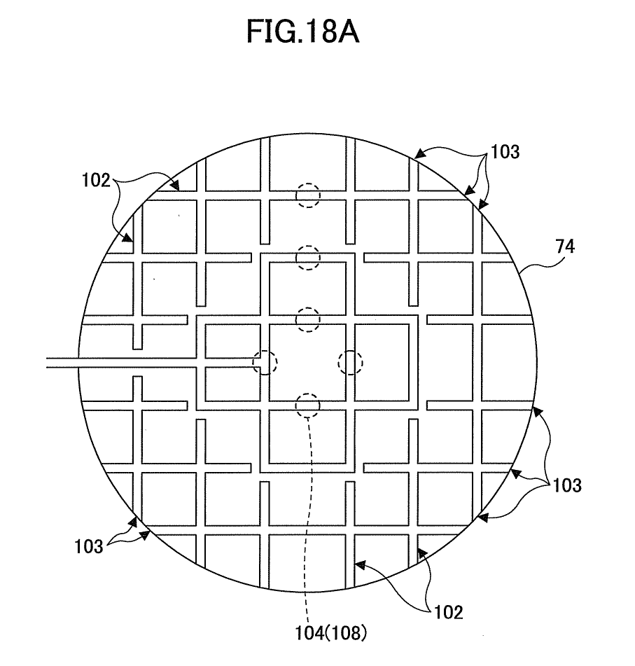

Incidentally, the gas conduits 102 may be configured as shown in FIGS. 17A and 17B, in addition to the previous examples.

FIGS. 17A and 17B illustrate a modified example of an arrangement of the gas conduits. FIG. 17A illustrates gas conduits 102 that are arranged in a grid pattern and in gaseous communication with one another, because of the grid pattern arrangement. In this case, each of the gas conduits 102 may be open when the gas inlet port 114 is used. Alternatively, the opening may be closed. In this case, the gas inlet 142 explained in Example 2 illustrated in FIG. 8 is formed in at least one of the gas conduits 102. Incidentally, FIG. 17A illustrates part of the gas conduits 102 having the gas ejection holes 104 into which the porous dielectric bodies 108 are mounted.

FIG. 17B illustrates the gas conduits 102 that are arranged in a concentric pattern with one another, where a straight gas conduit 102F is formed in order to be in gaseous communication with the ring-shaped gas conduits 102.

In this case, opening 103 at an end portion of the gas conduit 102F may be open when the gas inlet port 114 is used. With this, a gas for activating plasma such as Ar gas flows into the gas conduits 102, 102F through the gas inlet port 114. In addition, the openings 103 may be closed. In this case, the gas inlet 142 explained in Example 2 illustrated in FIG. 8 is formed in the gas conduit 102F. Incidentally, FIG. 17B illustrates part of the gas conduits 102 having the gas ejection holes 104 into which the porous dielectric bodies 108 are mounted.

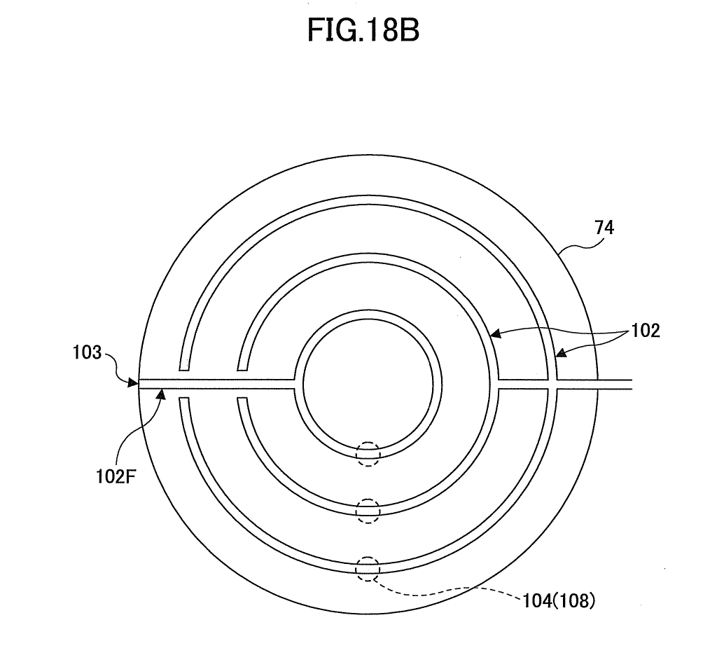

FIGS. 18A and 18B illustrate other modified examples of the top plate illustrated in FIGS. 17A and 17B. As shown in FIGS. 18A and 18B, the gas ejection holes 104 may be grouped into plural zones. Here, the gas ejection holes 104 are grouped into the first zone positioned in an inner portion and the second zone position outside of the first zone. In this case, the gas conduits are separated between the zones. In addition, gas inlets corresponding to the zones are closed with sealing members or the like.

Incidentally, although the ring pattern gas conduits 102 illustrated in FIGS. 17B and 18B and the grid pattern gas conduits 102 illustrated in 18A cannot be formed with a drill and laser beam, two circular plates are prepared; concave grooves corresponding to the gas conduits 102 are formed in one of the two circular plates; and the two circular plates are coupled by gluing, adhesion, or the like, thereby forming the top plate 74.

In addition, the configurations illustrated in FIGS. 17A and 17B may be applied in any one of Examples 1 through 5.

Incidentally, a primary constituent material of the porous dielectric body 108 is preferably the same as a primary constituent material of the top plate 74, taking into consideration a thermal expansion coefficient. For example, when quartz glass is used for the top plate 74, porous quartz is preferably used for the porous dielectric body 108; and when a ceramic material is used for the top plate 74, a porous ceramic material is preferably used for the porous dielectric body 108.

The ceramic material may include alumina, silica, calcium phosphate, SiC, zirconia, or the like. In addition, the porous ceramic material disclosed in Japanese Patent Application Laid-Open Applications No. 2002-343788, 2003-95764, 2004-59344, and the like may be used.

In addition, while the above examples are explained taking microwaves as an example of electromagnetic waves, not being limited to this, high frequency waves may be used, for example.

Moreover, while the film deposition is taken as an example of the plasma process here, not being limited to this, the present invention may be applied to other plasma processes including an etching process, an ashing process, and the like.

Furthermore, while the semiconductor wafer is taken as an example of an object to be processed here, the present invention may be applied to a glass substrate, a liquid crystal display (LCD) substrate, a ceramic substrate, and the like.

This international application claims priority based on a Japanese Patent Application No. 2007-232099, filed Sep. 6, 2007, the entire content of which are hereby incorporated herein by reference.

1. A top plate that is configured as a solid part and provided in an opening in a ceiling portion of a plasma process chamber whose inside is evacuatable to vacuum, the top plate comprising:
plural gas conduits formed in a horizontal direction of the top plate; and
gas ejection holes that are open in a first surface of the top plate, the first surface facing the inside of the plasma process chamber and in gaseous communication with the plural gas conduits.

2. The top plate recited in claim 1, wherein the plural gas conduits are open at respective ends as a gas inlet in a side surface of the top plate and extend toward a center portion of the top plate.

3. The top plate recited in claim 1, wherein the plural gas conduits include:
first gas conduits formed in a radial pattern toward the center portion of the top plate; and
second gas conduits formed in parallel with the first gas conduits.

4. The top plate recited in claim 1, wherein one of the plural gas conduits is in gaseous communication with at least another one of the plural gas conduits, and includes a gas inlet open in one of the first surface and a second surface of the top plate, the second surface opposing the first surface.

5. The top plate recited in claim 4, wherein the plural gas conduits are formed in a radial pattern in the top plate, and wherein the one of the plural gas conduits is in gaseous communication, at an end portion existing in a center portion of the top plate, with the at least another one of the gas conduits.

6. The top plate recited in claim 4, wherein the plural gas conduits include
a first group of the gas conduits that extend toward a center portion of the top plate; and
a second group of the gas conduits that are in gaseous communication with the first group of the gas conduits.

7. The top plate recited in claim 4, wherein the gas ejection holes in gaseous communication with the plural gas conduits are grouped into first zone gas ejection holes positioned in an inner circumferential portion of the top plate and second zone gas ejection holes positioned in an outer circumferential portion of the top plate,
wherein the plural gas conduits in gaseous communication with the first zone gas ejection holes are arranged in a radial pattern and in gaseous communication with one another at end portions existing in a center portion of the top plate, and
wherein the plural gas conduits in gaseous communication with the second zone gas ejection holes include a first group of the gas conduits that extend toward the center portion of the top plate and a second group of gas conduits that are in gaseous communication with the first group of the gas conduits.

8. The top plate recited in claim 4, wherein the gas ejection holes in gaseous communication with the plural gas conduits are grouped into first zone gas ejection holes positioned in an inner circumferential portion of the top plate and second zone gas ejection holes positioned in an outer circumferential portion of the top plate,
wherein the plural gas conduits in gaseous communication with the first zone gas ejection holes include a first group of the gas conduits that extend toward the center portion of the top plate and a second group of the gas conduits that are in gas communication with the plural gas conduits of the first group, and
wherein the plural gas conduits in gaseous communication with the second zone gas ejection holes include the second group of the gas conduits that are in gas communication with the plural gas conduits of the first group.

9. The top plate recited in claim 1, wherein the gas ejection holes in gaseous communication with the plural gas conduits are grouped into first zone gas ejection holes positioned in an inner circumferential portion of the top plate and second zone gas ejection holes positioned in an outer circumferential portion of the top plate;
wherein part of the plural gas conduits are in gaseous communication with one of the first zone gas ejection holes and the second zone gas ejection holes, have openings at respective ends in a side surface of the top plate, and extend toward the center portion of the top plate; and
wherein the remaining gas conduits include:
a first group of gas conduits that are in gaseous communication with the other one of the first zone gas ejection holes and the second zone gas ejection holes, and extend toward the center portion of the top plate, and
a second group of gas conduits that are in gaseous communication with the plural gas conduits of the first group.

10. The top plate recited in claim 1, wherein the plural gas conduits include:
ring-shaped gas conduits arranged in a concentric pattern, and
gas conduits that intersect to be in gaseous communication with the ring-shaped gas conduits.

11. The top plate recited in claim 1, wherein the plural gas conduits are formed in a grid pattern.

12. The top plate recited in claim 1, wherein porous dielectric bodies having an aeration property are mounted into the corresponding gas ejection holes.

13. The top plate recited in claim 1, wherein ceramic materials having fine holes are mounted into the corresponding gas ejection holes.

14. The top plate recited in claim 1, wherein a coolant conduit through which a coolant flows is formed in the top plate.

15. A plasma process apparatus comprising:
a process chamber that has an opening in a ceiling portion thereof and whose inside is evacuatable to vacuum;
a susceptor that is provided in the process chamber and on which an object to be processed is placed;
a top plate recited in claim 1 and provided onto the opening of the process chamber;
an electromagnetic wave introduction portion that introduces electromagnetic waves into the process chamber through the top plate; and
a gas supplying portion that supplies a gas to the gas conduits formed in the top plate.

16. The plasma process apparatus recited in claim 15, wherein the gas supplying portion includes a ring-shaped gas introduction port that is provided in a circumference of the top plate and supplies a gas to the gas conduits.

17. The plasma process apparatus recited in claim 15, wherein the gas introduction portion includes a gas supplying conduit that vertically extends in a sidewall of the process chamber and is in gaseous communication with a gas inlet of the gas conduits.

18. The plasma process apparatus recited in claim 15, wherein a gas introduction portion is provided inside the process chamber.

19. A method of manufacturing a top plate to be provided in an opening of a ceiling portion of a plasma process chamber whose inside is evacuatable to vacuum, the method comprising steps of
forming plural gas conduits inside the top plate by perforating the top plate from a side surface of the top plate; and
forming plural gas ejection holes to be in gaseous communication with the gas conduits by perforating the top plate from a surface of the top plate.

20. The method recited in claim 19, further comprising a step of mounting porous dielectric bodies having an aeration property into the corresponding gas ejection holes.

21. A method of manufacturing a top plate to be provided in an opening of a ceiling portion of a plasma process chamber whose inside is evacuatable to vacuum, the method comprising steps of:
forming plural gas conduits inside a half-finished product by perforating the half-finished product from a side surface of the half-finished product;
forming plural gas ejection holes to be in gaseous communication with the gas conduits by perforating the half-finished product from a surface of the half-finished product; and
sintering the half-finished product.

22. The method recited in claim 21, further comprising steps of:
forming a gas inlet open in one of an upper surface and a lower surface of the half-finished product so that the gas inlet is in gaseous communication with at least one of the plural gas conduits in the half-finished product; and
closing openings of the gas conduits formed in the side surface of the half-finished product.

23. The method recited in claim 21, further comprising a step of mounting porous dielectric bodies having an aeration property into the corresponding gas ejection holes.

24. The method recited in claim 21, further comprising a step of forming a coolant conduit through which a coolant flows by perforating the half-finished product from the side surface of the half-finished product.
